(19) United States
(12) Patent Application Publication
(10) Pub. No.: US 2002/0098705 A1
(43) Pub. Date: Jul. 25, 2002

(54) Single step chemical mechanical polish process to improve the surface roughness in MRAM technology

(75) Inventor: Kia-Seng Low, Hopewell Junction, NY (US)

Correspondence Address: Steven H. Slater, Slater & Matsil, L.L.P., Suite 1000, 17950 Preston Road, Dallas, TX, 75252, US

(73) Assignee: Infineon Technologies North America Corp.

(21) Appl. No.: 10/053,019

(22) Filed: Jan. 18, 2002

Related U.S. Application Data
(60) Provisional application No. 60/263,985, filed on Jan. 24, 2001.

(51) Int. Cl. H01L 21/311

(52) U.S. Cl. 438/698

(57) ABSTRACT

A method of lithographically forming a semiconductor device that reduces the effects of edge topography when misalignment occurs. The method comprises forming a dielectric layer (20) having a top surface, etching a trench (22) in the dielectric layer and depositing a liner (26) on the top surface of the dielectric layer and within the trench. A metal layer (24) is then deposited on the liner and polishes until the metal layer is coplanar with the liner on the top surface of the dielectric layer, leaving a portion of the liner exposed. A stack layer (32) is deposited atop the exposed liner and on the polished metal layer and patterned. The exposed liner and non-patterned portion of the stack layer are removed simultaneously. A magnetic RAM (MRAM) can be processed in which undesirable magnetic properties caused by mis-alignment of the magnetic stack are minimized because of the improved edge topography.

### TECHNICAL FIELD OF THE INVENTION

This invention relates to semiconductor devices and more particularly to a method for formation of semiconductor devices utilizing chemical mechanical polishing with improved surface topography.

### BACKGROUND OF THE INVENTION

A growing trend in semiconductor processing is the use of chemical mechanical polishing (CMP) to form semiconductor devices. CMP is used to, among other things, planarize the metal which is used to define interconnects in a semiconductor device. CMP is particularly useful in processes which use copper to form the interconnects of semiconductor devices using a dual damascene approach in which holes and trenches are formed within a dielectric, then filled with copper. Because copper is a better conductor and has better electromigration resistance than many traditional semiconductor metals (i.e. aluminum), copper is increasingly being used in the formation of semiconductor devices. Thus, the refinement of the CMP process is of even greater importance to the semiconductor industry.

When a conventional CMP process is used, the edges of pattern features tend to have additional edge topography 11 as shown on the substrate 10 in FIGS. 1a and 1b. As shown in perspective view in FIG. 1a and plan view in FIG. 1b, various features may be formed on the surface of substrate 10. In one manner, these features can include protrusions 6 that extend above the surface 4 of the substrate 10. In other embodiments, the features could include trenches that extend below the surface of the substrate that may be subsequently filled with some material, such as a conductive material. As will be explained in greater detail below, edge topography results from the commonly preferred processing step(s) of chemical mechanical polishing of the materials forming features 6 (or of the materials that fill a trench 6, not shown). This edge topography may adversely impact device performance, particularly with magnetic random access memory (MRAM) devices.

MRAM devices are increasingly being used because they have the advantage of non-volatility, capability of three dimensional cell packing, lower power consumption, and simpler and cheaper processing compared to conventional DRAM and nonvolatile flash memory. MRAM devices use the relative orientation of the magnetization in the ferromagnetic materials to store information. The relative orientation and switching of the magnetization can be corrupted by surface roughness or additional edge topography. The additional edge topography will distort or cause pinning effects on the magnetic field of the domains in the ferromagnetic materials. Distortion or pinning results in undesirable magnetostatic fields. Also, the additional edge topography may introduce a short through the thin magnetic tunneling junction when the magnetic stack is deposited over the edge topography.

### SUMMARY OF THE INVENTION

These and other problems are generally solved or circumvented, and technical advantages are generally achieved, by the present invention that includes a method for removing topography features resulting from chemical mechanical polishing. The invention advantageously provides for an improved surface for subsequent processing, including but not limited to formation of MRAM devices on the surface.

A preferred method of lithographically forming a semiconductor device comprises forming a dielectric layer having a top surface and etching a trench in the dielectric layer. A liner is then deposited on the top surface of the dielectric layer and within the trench. A metal layer is deposited on the liner and polished until the metal layer is coplanar with the liner on the top surface of the dielectric layer, leaving a portion of the liner exposed. A stack layer is then deposited atop the exposed liner and on the polished metal layer and patterned to result in a patterned and non-patterned portion of the stack layer. The non-patterned portion of the stack layer and the exposed liner are removed simultaneously.

One advantage of a preferred embodiment of the present invention is that it reduces edge topography that adversely affects planarization.

A further advantage of a preferred embodiment of the present invention is that it reduces the corruptive effects of edge topography on the magnetization of MRAM devices.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1a-1b show the additional edge topography on a semiconductor device which can adversely affect device performance;

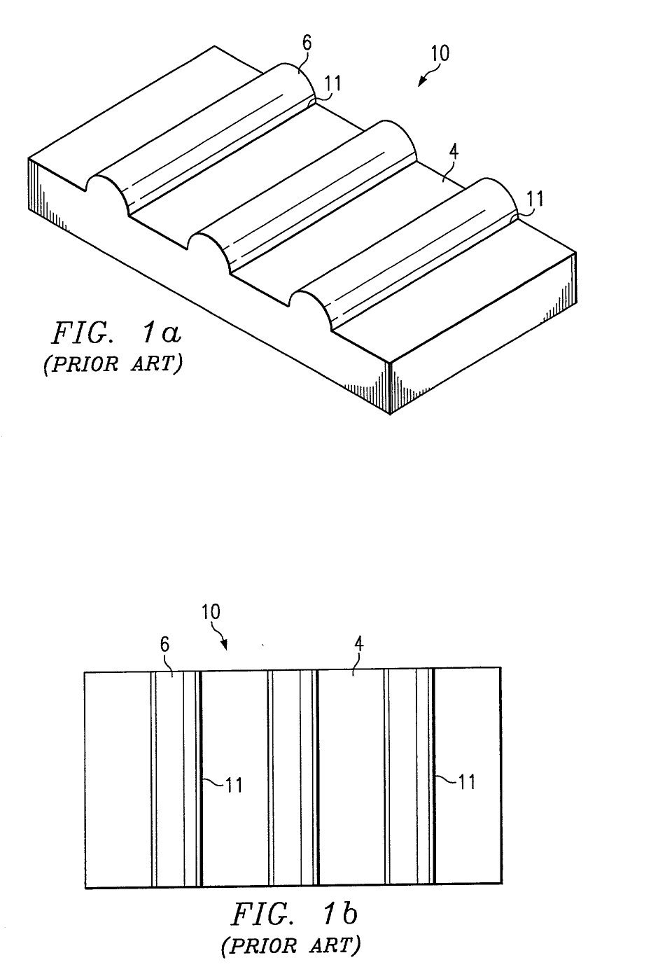

FIGS. 2a-2e show a prior art method of forming the prior art semiconductor device;

FIGS. 3a-3c illustrate the misalignment and polish of the prior art method of forming the prior art semiconductor device;

FIGS. 4a-4d illustrate a preferred method of the present invention; and

FIGS. 5a-5cillustrate the polishing effects on a semiconductor device utilizing a preferred method of the present invention.

### DETAILED DESCRIPTION OF THE PREFERRED EMBODIMENT

The making and using of the presently preferred embodiment is discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A first preferred embodiment of the present invention is a method for minimizing and/or removing the topography resulting from using chemical mechanical polishing (CMP). Although the present invention will be discussed in the context of MRAM applications, it should be appreciated by those skilled in the art that the present invention may be utilized in other applications.

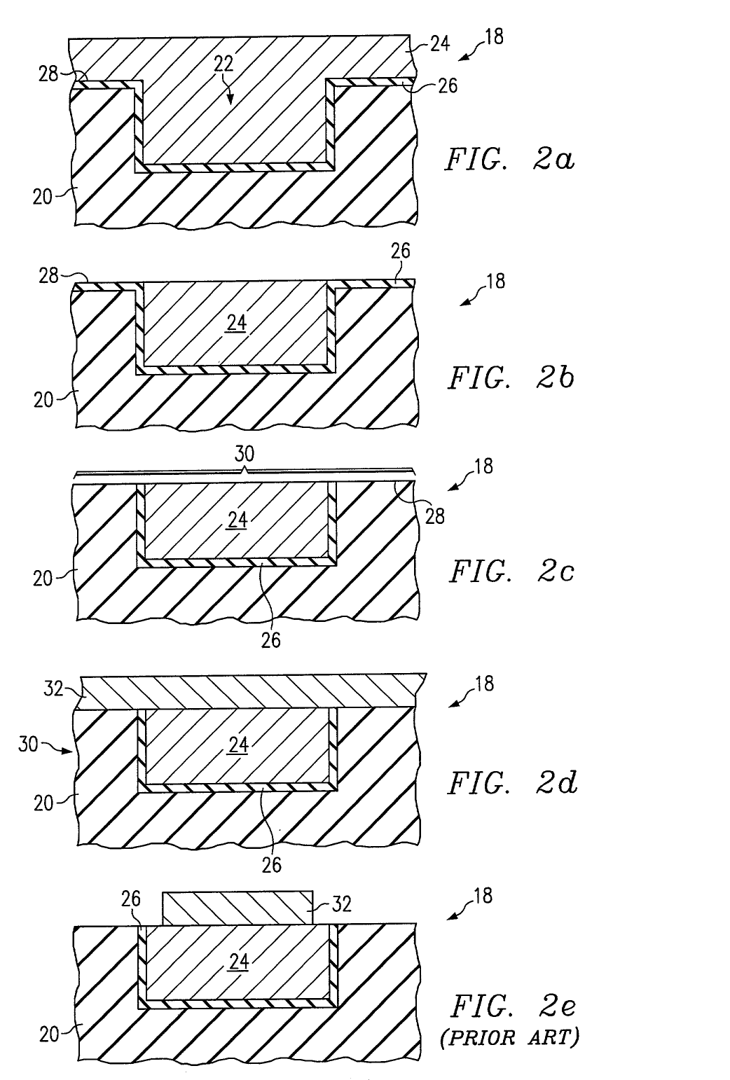

FIGS. 2a-2e illustrate the prior art method of forming a prior art semiconductor device 18 using known damascene processes. The dielectric layer 20 includes a trench 22 in which a metallic material 24 has been deposited on top of a liner 26. The liner 26 also extends across the top surface 28 of the dielectric layer 20. The liner 26 prevents the metallic material 24 from diffusing into the dielectric layer 20 and/or silicon. The metallic material 24 is a conductive material such as aluminum or copper. FIG. 2b represents the device 18 after the first step polish of a conventional CMP has been performed. The conventional CMP process is a two-step process in which the first step polish includes removing the excess metallic material 24. The first step polish removes the bulk of the metallic material 24 that resides on the top surface 28 but stops short of removing the liner 26.

The second step polish removes the liner 26 on the top surface 28 resulting in a planar surface 30 as shown in FIG. 2c. The second step polish typically uses different polishing slurry than that used for the first step polish because of the differing polish rates of the liner 26 and metallic material 24 (in some applications, different polishing pads may be used as well, but this is not necessary to the invention). Once the conventional CMP process is finished, a stack layer 32, in this case a magnetic stack layer, is deposited on the planar surface 30 as illustrated in FIG. 2d. This stack layer 32 is typically comprised of a series of layers of one or more of nickel, iron, cobalt, platinum, manganese, metallic oxides, or other suitable magnetic material or compound. The magnetic stack layer is then etched to result in the device 18 as illustrated in FIG. 2e.

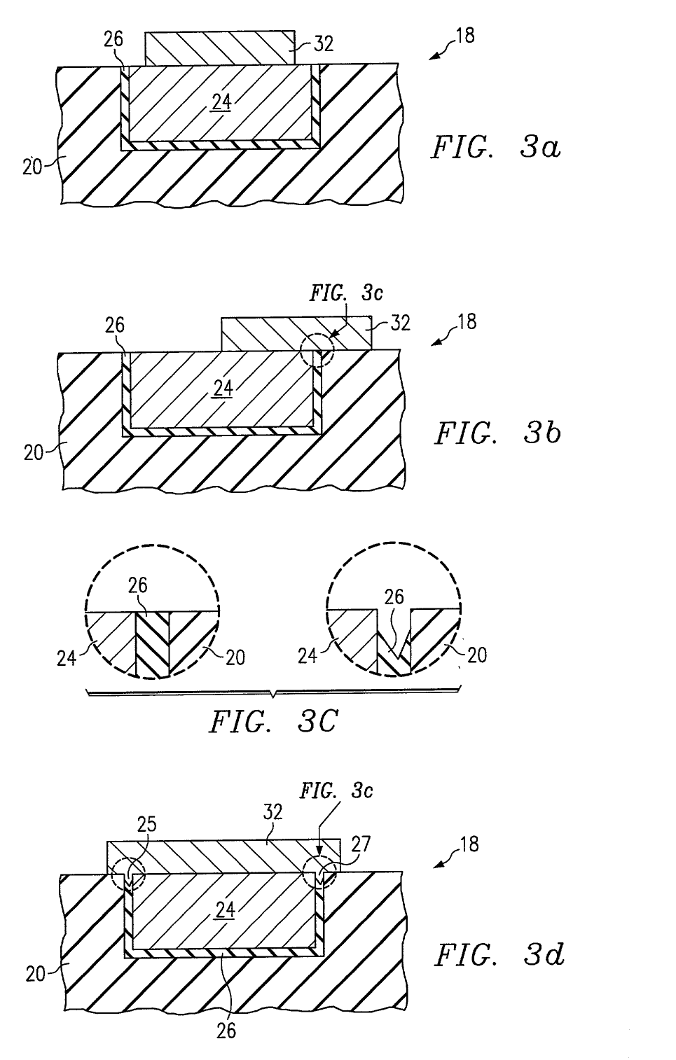

When the device has ideal alignment between the stack layer 32 and the metallic material 24, as shown in FIG. 3a, the conventional CMP process provides sufficient planarization within an acceptable tolerance. However, real world processes will typically result in some mis-alignment as shown (in exaggerated scale) in FIG. 3b. In this case, the two CMP polish steps result in the liner 26 being severely eroded and the dielectric layer 20 and the metallic material 24 being subject to dishing. The resulting topography for an ideal case versus a non-ideal real world process result is illustrated in FIG. 3c. The non-ideal edge topography illustrated in the figure may result in the need for an intermediate step to restore planalarity before deposition of the stack layer 32. The intermediate step adds cost and complexity to the process. FIGS. 3a and 3b illustrate the case where the magnetic stack 32 is smaller than the underlying line 24. Irregular topography can also effect device performance when the magnetic stack 32 is wider than the underlying metal line 24, even though alignment issues are not as critical, as illustrated by FIG. 3d. Note that in FIG. 3d, the magnetic stack 32 overlies two regions of edge topography, 25 and 27, even when the stack is well aligned. The edge topography illustrated in both FIGS. 3b and 3d can be lessened by the preferred embodiments of the present invention that provides for a single step CMP process, as explained below.

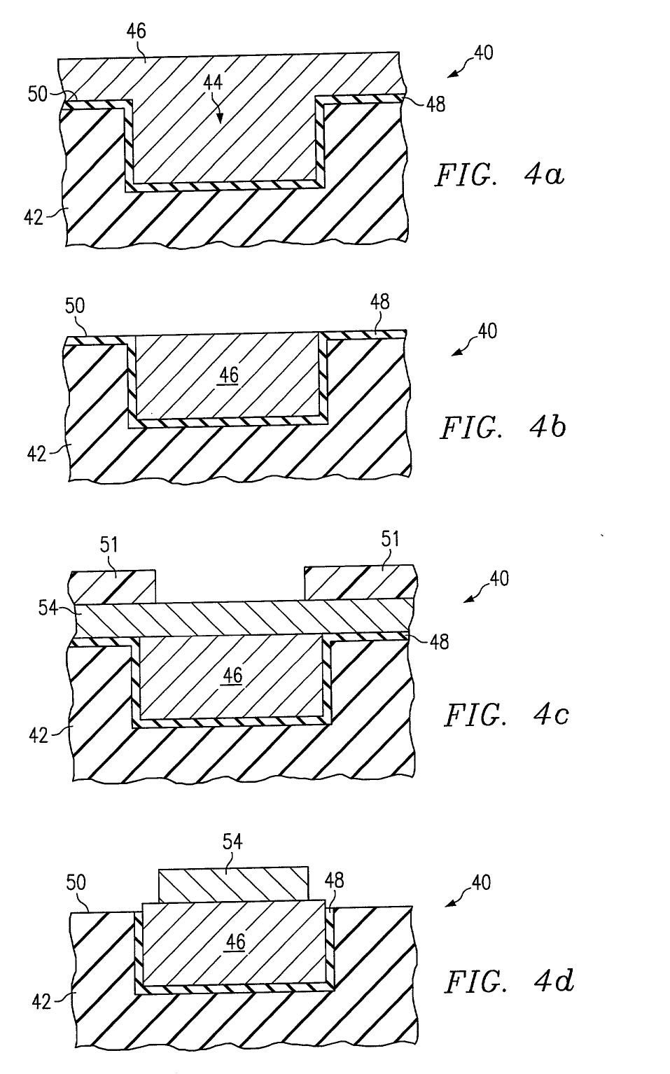

FIGS. 4a-4d illustrate the method by which a preferred embodiment of the present invention can be processed. FIG. 4a shows a semiconductor device 40 at the relevant stage of processing. The dielectric layer 42 has a trench 44 in which a metallic material 46 has been deposited on top of a liner 48. The liner 48 may be comprised of tantalum, tantalum nitride, titanium, titanium nitride, or tungsten nitride and also extends to the top surface 50 of the dielectric layer 42. The typical range of thickness for the liner 48 is typically in the range of 300 Angstroms to 600 Angstroms and more preferably about 500 Angstroms. The dielectric layer 42 may comprise, but is not limited to, silicon dioxide or a low dielectric constant (low-k) material such as SILK. The metallic material 46 may be any suitable metal, but is preferably copper.

FIG. 4b illustrates the single step CMP which removes the bulk of the metallic material 46 on the top surface 50 but leaves the liner 48 in contrast to the two-step conventional CMP process in which a second CMP step is performed to remove the liner 48. The slurry is typically comprised of abrasive particles, an oxidizer, a corrosion inhibitor, and additives. The oxidizer may be hydrogen peroxide, hydroxylamine, or potassium iodate, or some combination thereof.

The magnetic stack layer 54 is then deposited on top of both metallic material 46 and liner 48 as shown in FIG. 4c. The patterning of the stack layer 54 utilizes a photoresist layer 51 that has been patterned using conventional photolithography. The masking process results in the stack layer 54 having exposed and non-exposed portions. The masking process is followed by the etch, preferably a plasma etch, of the stack layer 54 to remove the exposed portions of the stack layer 54 to result in the pattern as shown in FIG. 4d. At the time of etch, not only are the exposed portions of the stack layer 54 removed, but the liner 48 that remains on the top surface 50 is simultaneously removed during the magnetic stack etch. Simultaneous removal of the exposed portion of the stack layer 54 and the liner 48 eliminates the need for a second step in the CMP process as in the prior art. The elimination of the second step decreases the chances of dishing and eroding which is particularly problematic when mis-alignment of the stack layer 54 occurs. FIG. 4d illustrates the resulting device in which the metallic material 46 extends a distance t above the top surface 50. This distance t is substantially equal to the thickness of the liner 48.

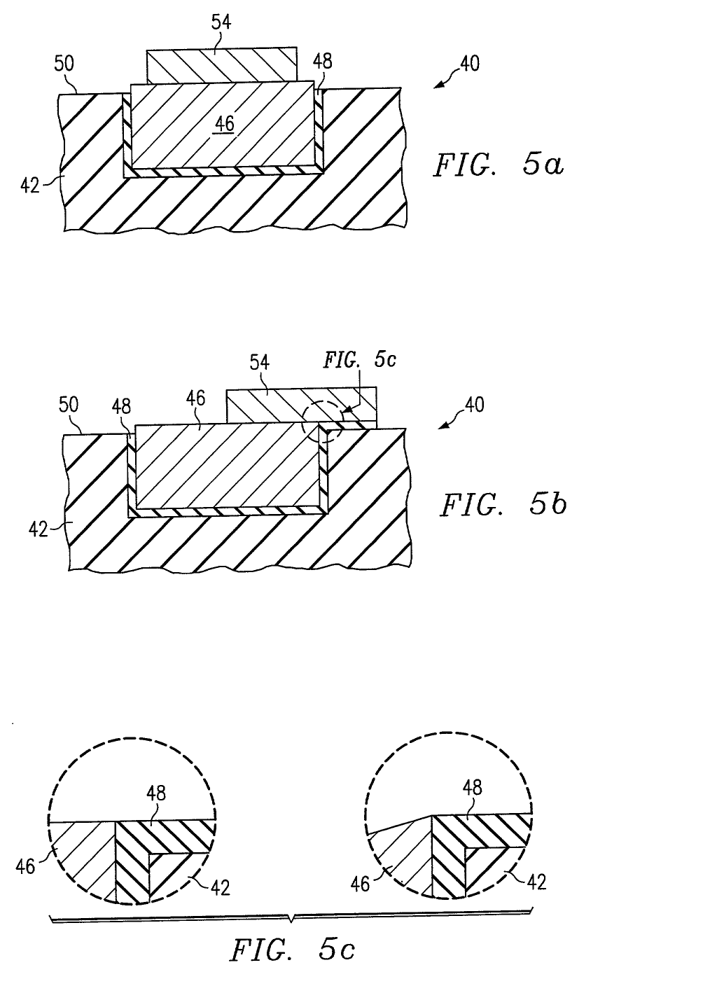

FIG. 5a illustrates the ideal alignment of the stack layer 54 and the metallic material 46. As shown in FIG. 5b, real world processes may result in some mis-alignment during the processing of the semiconductor device. Typically semiconductor manufacturers increased the width of the features to lesson the possibility of mis-alignment. This increases the device size that is undesirable. Additionally, mis-alignment could still occur. Thus, increasing the width of the features does not address the problem of mis-alignment if it does occur. The present invention does address the problem of mis-alignment after it has occurred. As illustrated in FIG. 5c, the unfavorable effects of polishing a device in which mis-alignment has occurred is lessoned because the additional polishing step has been removed. Also note that the device illustrated in FIG. 3d, in which the magnetic stack is wider than the underlying metal line, would also benefit from the improved edge topography offered by the above described embodiments of the invention. As shown, some minor dishing of the metallic material 46 may occur but the liner 48 is not severely eroded as in the prior art because etching as opposed to polishing is used to remove the liner 48 across the top surface of the dielectric.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, manufacture, composition of matter, means, methods and steps described in the specification. As one of ordinary skill in the art will readily appreciate from the disclosure of the present invention, processes, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, manufacture, compositions of matter, means, methods, or steps.

What is claimed is:

1. A method of forming a semiconductor device, the method comprising:
forming a dielectric layer having a top surface;
etching a trench in the dielectric layer;
depositing a liner on the top surface of the dielectric layer and within the trench;
depositing a metal layer on the liner;
polishing the metal layer until the metal layer is coplanar with the liner on the top surface of the dielectric layer, leaving a portion of the liner exposed;
depositing a stack layer atop the exposed liner and on the polished metal layer;
patterning the stack layer to result in a patterned and a non-patterned portion of the stack layer; and
removing the non-patterned portion of the stack layer and the exposed liner simultaneously.

2. The method as in claim 1 wherein the metal layer is comprised of copper.

3. The method as in claim 1 wherein the dielectric layer is comprised of a material selected from the group consisting of silicon dioxide, fluorinated oxide, and SILK.

4. The method as in claim 1 wherein the liner layer is comprised of a material selected from the group consisting of titanium, titanium nitride, tungsten nitride, tantalum, and tantalum nitride.

5. The method as in claim 1 wherein the semiconductor device is a magnetic random access memory (MRAM).

6. The method as in claim 5 wherein the stack layer is a magnetic stack layer.

7. The method as in claim 1 wherein the polishing is chemical mechanical polishing.

8. The method as in claim 7 wherein the liner is in the range of 300 Angstroms to 600 Angstroms in thickness.

9. A semiconductor device comprising:
a dielectric layer having a top surface;
a trench formed within the dielectric layer;
a liner formed within the trench, the liner having a thickness t;
a metal layer deposited within the trench, the metal layer extending at least a distance t above the top surface of the dielectric layer; and
a patterned stack layer formed on top of the metal layer.

10. The device as in claim 9 wherein the device is a magnetic random access memory.

11. The device as in claim 10 wherein the stack layer is a magnetic stack layer.

12. The method as in claim 9 wherein the metal layer is comprised of copper.

13. The method as in claim 9 wherein the dielectric layer is comprised of a material selected from the group consisting of silicon dioxide, fluorinated oxide, and SILK.

14. The method as in claim 9 wherein the metal layer extends a distance above the top surface of the dielectric layer, the distance equal to t.

15. The method as in claim 9 wherein the liner layer is comprised of a material selected from the group consisting of titanium nitride, tungsten nitride, tantalum, tantalum nitride and titanium.

16. The method as in claim 9 wherein the polishing is chemical mechanical polishing.

17. The method as in claim 16 wherein the removal of the liner layer is accomplished by etching.

18. A semiconductor device comprising:
a dielectric layer having a top surface;
a trench formed within the dielectric layer;
a liner formed within the trench, the liner having a thickness t;
a metal layer deposited within the trench, the metal layer extending at least a distance t above the top surface of the dielectric layer; and
a magnetic stack layer formed on top of the metal layer.

19. The method as in claim 18 wherein the metal layer is comprised of copper.

20. The method as in claim 18 wherein the dielectric layer is comprised of a material selected from the group consisting of silicon dioxide, fluorinated oxide, and SILK.

21. The method as in claim 18 wherein the liner layer is comprised of a material selected from the group consisting of titanium nitride, tungsten nitride, tantalum, tantalum nitride and nitride.
